(19) United States
(12) Patent Application Publication
(10) Pub. No.: US 2023/0199943 A1
(43) Pub. Date: Jun. 22, 2023

(54) RADIO-FREQUENCY MODULE

(71) Applicant: Murata Manufacturing Co., Ltd., Nagaokakyo-shi (JP)

(72) Inventors: Kazuhito TONOE, Nagaokakyo-shi (JP); Hirotsugu MORI, Nagaokakyo-shi (JP)

(73) Assignee: Murata Manufacturing Co., Ltd., Nagaokakyo-shi (JP)

(21) Appl. No.: 18/113,636

(22) Filed: Feb. 24, 2023

Related U.S. Application Data
(63) Continuation of application No. PCT/JP2021/027710, filed on Jul. 27, 2021.

(30) Foreign Application Priority Data
Aug. 24, 2020 (JP) 2020-140572

(51) Int. Cl. H05K 1/02; H05K 1/11; H03H 9/64

(52) U.S. Cl. CPC H05K 1/0243; H03H 9/6483; H05K 1/115; H05K 2201/1006

(57) ABSTRACT

A radio-frequency module is provided that includes a structure, a filtering element disposed on the structure, a switching element embedded in the structure, and an impedance element connected to the switching element and the filtering element. In a plan view of the structure, the switching element and the filtering element overlap each other in at least part thereof. The structure has a plurality of vias including a via , a via and a via. The via connects the input-output terminal and the filtering element. The via connects the ground terminal and an impedance adjustment circuit including the switching element and the impedance element. In a plan view, the via is located in a smallest rectangular region encompassing the vias.

### CROSS-REFERENCE TO RELATED APPLICATIONS

The present application is a continuation of International Application No. PCT/JP2021/027710, filed Jul. 27, 2021, which claims priority to Japanese Patent Application No. 2020-140572, filed in the Japanese Patent Office on Aug. 24, 2020, the entire contents of each of which is incorporated herein by reference in its entirety.

### TECHNICAL FIELD

This disclosure relates to a radio-frequency module, more particularly to a radio-frequency module equipped with a structure and an electronic component.

### BACKGROUND ART

Among the known devices in the relevant technical field is the SAW device mounted with a multilayer wiring board including a thermosetting resin layer and a thermoplastic resin layer, a capacitor, a semiconductor integrated circuit bare chip, and a SAW piezoelectric element. The capacitor and the semiconductor integrated circuit bare chip are embedded in the thermosetting resin layer, and the SAW piezoelectric element is mounted on the thermoplastic resin layer. The SAW device thus characterized is expected to expedite and facilitate miniaturization.

### CITATION LIST

### Patent Literature

PTL 1: Japanese Patent Laying-Open No. 2006-211613

### SUMMARY

### Technical Problems

With further miniaturization of such a radio-frequency module as the SAW device, the layout density of wiring and via conductors may correspondingly increase, leading to a higher risk of property degradation.

To address the issues of the known art, this disclosure is directed to providing a radio-frequency module further reducible and still allowed to control property degradation.

### Solutions to Problems

According to one non-limiting aspect of the disclosure, a radio-frequency (RF) module includes: a structure having a first main surface and a second main surface that are opposed to each other; a filtering element disposed on the first main surface of the structure; a switching element embedded in the structure; and an impedance element embedded in the structure and connected to the switching element and the filtering element. The switching element and the filtering element at least partially overlap each other in a plan view in a normal direction to the first main surface. An input-output terminal and a first ground terminal that are disposed on the second main surface of the structure. The structure has a plurality of vias arranged in the normal direction to the first main surface. The plurality of vias include a first via, a second via and a third via. The first via connects the input-output terminal and the filtering element. The second via connects the first ground terminal and an impedance adjustment circuit having the switching element and the impedance element. The third via is located in a smallest rectangular region encompassing the first via and the second via in the plan view. The impedance element is interposed between the switching element and the filtering element in the normal direction to the first main surface.

### Advantageous Effects of Disclosure

This disclosure, while allowing a radio-frequency module to be further miniaturized, may successfully control the risk of property degradation possibly caused by unwanted coupling of vias and resulting signal skipping.

### BRIEF DESCRIPTION OF DRAWINGS

FIG. 1 is a perspective view of a radio-frequency module according to a first embodiment.

FIG. 2 is a cross-sectional view of the radio-frequency module according to the first embodiment.

FIG. 3 is an exploded perspective view of the radio-frequency module according to the first embodiment.

FIG. 4 is an equivalent circuit diagram of the radio-frequency module according to the first embodiment.

FIG. 5 is a layout diagram of vias in the radio-frequency module according to the first embodiment.

FIG. 6 is an equivalent circuit diagram of a radio-frequency module according to a first modified example.

FIG. 7 is a cross-sectional view of a radio-frequency module according to a second modified example.

FIG. 8 is a layout diagram of vias in a radio-frequency module according to a third modified example.

FIG. 9 is an equivalent circuit diagram of a radio-frequency module according to a second embodiment.

FIG. 10 is an equivalent circuit diagram of a radio-frequency module according to a fourth modified example.

FIG. 11 is a layout diagram of vias in a radio-frequency module according to a third embodiment.

FIG. 12 is an equivalent circuit diagram of the radio-frequency module according to the third embodiment.

FIG. 13 is a cross-sectional view of a radio-frequency module according to a fourth embodiment.

FIG. 14 is a cross-sectional view of a radio-frequency module according to a fifth embodiment.

FIG. 15 is a cross-sectional view of a radio-frequency module according to a fifth modified example.

FIG. 16 is a cross-sectional view of a radio-frequency module according to a sixth embodiment.

FIG. 17 is an equivalent circuit diagram of a radio-frequency module according to a seventh embodiment.

### DESCRIPTION OF EMBODIMENTS

Embodiments of the invention disclosed herein are hereinafter described. The embodiments are, however, described by way of example only and should not necessarily limit the scope of the teachings of the present disclosure.

In the drawings used to describe the embodiments, functionally similar or identical parts and components are illustrated with the same reference signs. The drawings used in the embodiments are schematically illustrated, in which the drawn objects may differ in size and proportion from the real objects. In some drawings, the same objects may be drawn in different sizes and proportions. The real sizes and proportions of the drawn objects should be estimated with reference to the description given below.

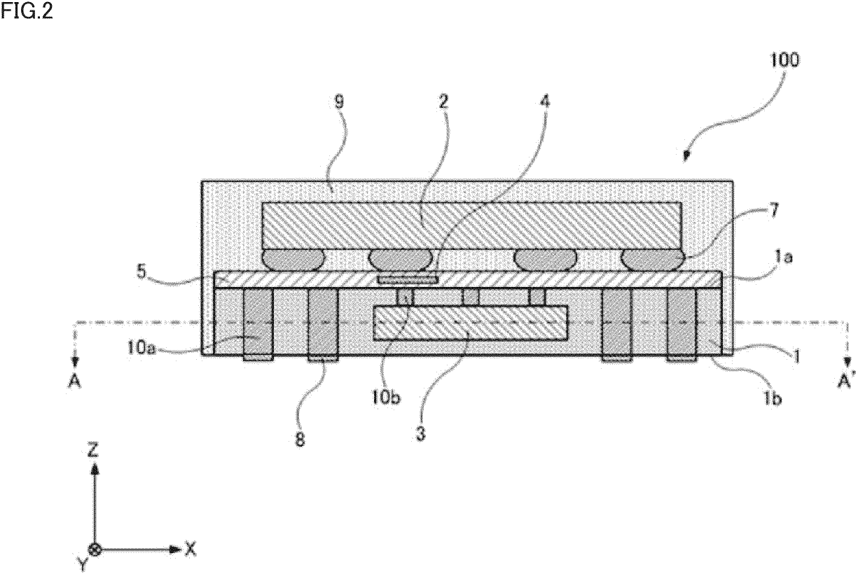

In the radio-frequency module described in the specification and claims, whichever side of the module may be its upper or lower side. In the description below, however, an orthogonal XYZ coordinate system is used, in which one side along the arrow of Z direction (upper side on the drawing of FIG. 2) on X-Z plane is set as the upper side, while the other side opposite to the arrow of Z direction (lower side on the drawing of FIG. 2) is set as the lower side, based on which the terms; upper, lower, top and bottom, are defined and used.

### (First Embodiment)

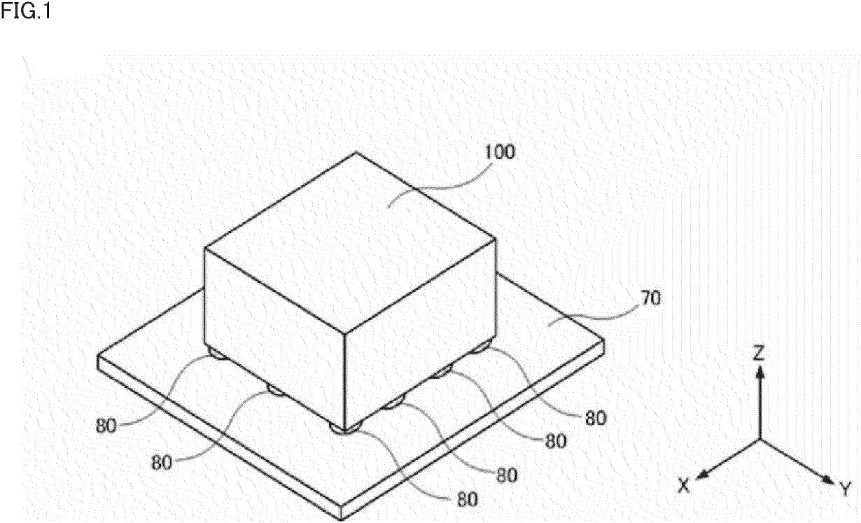

FIG. 1 is a perspective view of a radio-frequency module 100 according to a first embodiment. As illustrated in FIG. 1, radio-frequency module 100 is connected to a circuit board 70 through electrically conductive electrodes 80. Circuit board 70 may be, for example, a printed wiring board. Electrodes 80 having electrical conductivity may be columnar electrodes. Radio-frequency module 100 is thus electrically connected to circuit board 70.

### Overall Structural Features of Radio-Frequency Module

First, structural features of radio-frequency module 100 are hereinafter described with reference to FIG. 2.

FIG. 2 is a cross-sectional view of radio-frequency module 100 according to the first embodiment. As illustrated in FIG. 2, radio-frequency module 100 is equipped with a structure 1 having a first main surface 1a and a second main surface 1b opposed to each other, a filtering element 2, a switching element 3, and an impedance element 4. Filtering element 2 is disposed on first main surface 1a with solder bumps 7 being interposed therebetween. Switching element 3 is embedded in structure 1. Switching element 3 and filtering element 2 overlap each other in at least part thereof in a plan view in a normal direction (Z direction) to the first main surface 1a. Impedance element 4 is embedded in structure 1.

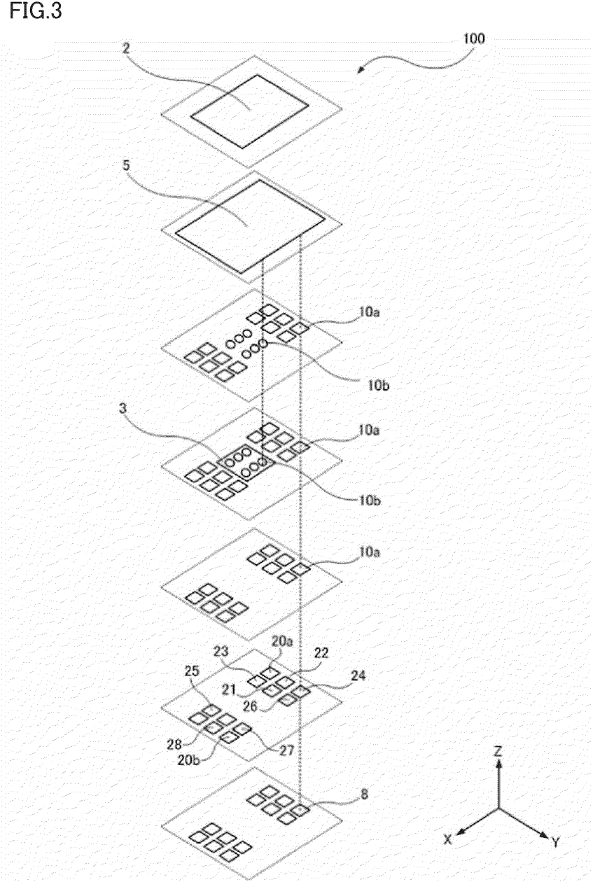

FIG. 3 is an exploded perspective view of radio-frequency module 100 according to the first embodiment. This drawing shows, from the top, filtering element 2, a wiring layer 5 with impedance element 4 being included therein, and switching element 3. Terminal electrodes 8 are disposed below vias 10a, and switching element 3 is disposed below vias 10b. Vias 10a and 10b may be hereinafter correctively referred to as via(s) 10.

### Component Elements of Radio-Frequency Module

First, component elements of radio-frequency module 100 are hereinafter described with reference to the drawings.

### (2.1) Structure

Structure 1 is a molded body having a plate-like shape, as illustrated in FIGS. 2 and 3. In structure 1 are retainable switching element 3, wiring layer 5 and vias 10. The shape of structure 1 viewed in Z direction is rectangular, however, may be otherwise, for example, elliptical. Structure 1 viewed in the direction of its thickness is larger than filtering element 2, switching element 3, wiring layer 5 and vias 10.

Structure 1 is formed using, for example, a resin having electrical insulating properties. Structure 1 may include, other than the resin, a filler which is contained in the resin. The filler, however, is not an indispensable material. The resin may be an epoxy resin. Examples of the resin may include, other than the epoxy resin, polyimide resin, acrylic resin, urethane resin, silicon resin, and maleimide resin. The filler may be an organic filler, for example, silica or alumina. Structure 1 may include, other than the resin and the filler, a black pigment such as carbon black. Structure 1 may be formed using ceramics.

Structure 1 is further embedded with wiring layer 5 and vias 10; columnar electrodes. Terminal electrodes 8 are formed on second main surface 1b. A plurality of vias 10 extend lengthwise in Z direction and include vias 10a and 10b. Wiring layer 5 is formed along first main surface 1a of structure 1. Wiring layer 5 includes impedance element 4 embedded therein. Wiring layer 5 and impedance element 4 are electrically connected to each other. Filtering element 2 is connected to wiring layer 5 with solder bumps 7 being interposed therebetween. Further, terminal electrodes 8 are connected to wiring layer 5 through vias 10a, and switching element 3 is connected to wiring layer 5 through vias 10b. Thus, filtering element 2, switching element 3 and impedance element 4 are electrically connected to one another. The connection relationship will be described in detail later in (3) circuit configuration.

### (2.2) Filtering Element

Filtering element 2 is an elastic wave device. The filtering element described herein may be a SAW (Surface Acoustic Wave) filter. Optionally, a BAW (Bulk Acoustic Wave) filter or a waveguide filter may be used instead of the SAW filter. This filtering element is not necessarily an elastic wave device and may be a dielectric filter or an LC filter.

Filtering element 2 may be a rectangular cuboid elongated in X direction. Switching element 3, though rectangular when viewed in Y direction, may be shaped otherwise, for example, square.

Filtering element 2 is disposed on first main surface 1a of structure 1 with solder bumps 7 being interposed therebetween. Filtering element 2 may be directly disposed on first main surface 1a of structure 1, or another element(s) may be interposed between filtering element 1 and first main surface 1a of structure 1.

### (2.3) Switching Element

Switching element 3 described herein includes a CMOS (Complementary Metal Oxide semiconductor). As a specific example, the SOI (Silicon on Insulator) process may be employed to configure this switching element. Switching element 3 may include at least one of GaAs, SiGe and GaN.

Switching element 3 may be, for example, a rectangular cuboid elongated in X direction. Switching element 3, though rectangular when viewed in Y direction, may be shaped otherwise, for example, square.

Switching element 3 is embedded in structure 1. Being “embedded” described herein includes a first state and a second state. The first state refers to a state in which one main surface of switching element 3 is uncovered with structure 1 (i.e., one main surface of switching element 3 is exposed from structure 1). The second state refers to a state in which any portion of switching element 3 but a portion for connection to an external circuit (including one main surface) is covered with structure 1. Looking at structure 1 in Z direction, filtering element 2, switching element 3, wiring layer 5 and impedance element 4 overlap one another in at least part thereof.

### (2.4) Impedance Element

A capacitor is used as impedance element 4 in radio-frequency module 100 according to the first embodiment. The capacitor described herein is just an example. Impedance element 4 may be, for example, an inductor or a resistor.

Impedance element 4 may be, for example, a rectangular cuboid elongated in X direction. Switching element 3, though rectangular when viewed in Y direction, may be shaped otherwise, for example, square. Impedance element 4 is embedded in wiring layer 5 in radio-frequency module 100 according to the first embodiment. Impedance element 4 is hence interposed between switching element 3 and filtering element 2 in Z direction.

Thus, impedance element 4 is electrically connected to switching element 3 and filtering element 2. The connection relationship will be described in detail later in (3) circuit configuration.

### (2.5) Wiring Layer

Wiring layer 5 is formed, for example, along first main surface 1a of structure 1. Wiring layer 5 is a rectangular cuboid elongated in X direction. Wiring layer 5 viewed in Y direction has a rectangular shape, however, may instead have, for example, a square shape. Wiring layer 5 is a multilayer body including a resin layer and a metal layer. In description of the electrical connections, for example, the metal layer included in wiring layer 5 may be referred to as wiring layer 5.

Impedance element 4 is embedded in wiring layer 5. Wiring layer 5 and impedance element 4 are electrically connected to each other. Filtering element 2 is connected to wiring layer 5 with solder bumps 7 being interposed therebetween. Further, terminal electrodes 8 and switching element 3 are connected to wiring layer 5 through vias 10.

Wiring layer 5 may be a single alloy or metal layer or a multilayer body including two or more alloy or metal layers. In radio-frequency module 100 according to this embodiment, wiring layer 5 may be formed from a material obtained by adding, to copper, at least one selected from the group consisting of chrome, nickel, iron, cobalt and zinc. Wiring layer 5 may be a multilayer body including copper and titanium.

### (2.6) Via

In radio-frequency module 100 according to the first embodiment, a plurality of vias 10 is retained in structure 1, as illustrated in FIG. 2. Vias 10 include vias 10a that connect wiring layer 5 and terminal electrodes 8 and vias 10b that connect wiring layer 5 and switching element 3. Vias 10a are disposed on lateral sides of switching element 3 in X direction, as illustrated in FIG. 3. Vias 10b are disposed in the upper direction of switching element 3. Vias 10 are spaced apart from one another on XY plane.

Each via 10 may be, for example, a rectangular cuboid elongated in Z direction of structure 1. Instead of such a shape, each via 10 may be shaped in, for example, a cylindrical form.

The material of each via 10 may be a metal. In radio-frequency module 100 according to the first embodiment, the material of each via 10 may be copper or gold.

### (2.7) Terminal Electrode

A plurality of terminal electrodes 8 are disposed on second main surface 1b of structure 1. Terminal electrodes 8 are each electrically connected to wiring layer 5 through a corresponding one of vias 10.

Terminal electrodes 8 have ground terminals 21 to 28 connected to the ground and input-output terminals 20 (20a, 20b) of radio-frequency module 100.

Terminal electrodes 8 may be each a multilayer electrode including a nickel layer and a gold layer. Instead, terminal electrodes 8 may be each a monolayer electrode.

### (2.8) Protective Layer

In radio-frequency module 100 according to the first embodiment, filtering element 2 and structure 1 are covered with a protective layer 9, as illustrated in FIG. 2. The material of protective layer 9 may be a synthetic resin, examples of which include epoxy resin or polyimide resin. In this description, protective layer 9, when viewed in Y direction of structure 1, is larger than structure 1. Protective layer 9 is thus large enough to contain therein structure 1 and filtering element 2.

Protective layer 9, instead of covering the whole structure 1 and filtering element 2, may be used to cover filtering element 2 alone. Protective layer 9 and structure 1 may not necessarily be equal in length in X direction. For example, protective layer 9 may be smaller in length than structure 1 in X direction.

### Circuit Configuration

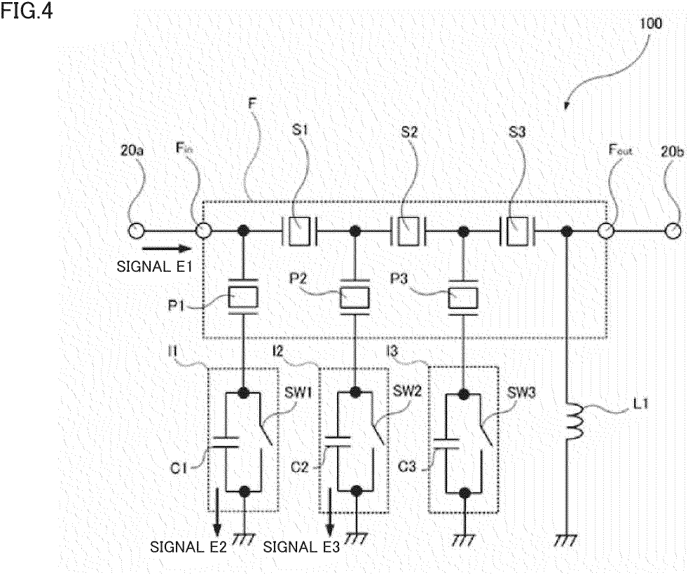

The structural features of radio-frequency module 100 were thus far described. Next, a circuit configuration provided by radio-frequency module 100 is hereinafter described. FIG. 4 is an equivalent circuit diagram of radio-frequency module 100.

As illustrated in FIG. 4, filtering element 2 is a ladder filter F having a plurality of series arm resonators S1 to S3 and a plurality of parallel arm resonators P1 to P3.

In the sequential order from the side of input terminal Fin, series arm resonator S1, series arm resonator S2 and series arm resonator S3 are connected in series to between an input terminal Fin and an output terminal Fout.

Parallel arm resonators P1 to P3 are connected to between the ground and the path that connects input terminal Fin and output terminal Fout. Specifically, parallel arm resonator P1 is connected to between the ground formed by ground terminal 21 and the path that connects input terminal Fin and series arm resonator S1. Parallel arm resonator P2 is connected to between the ground formed by ground terminal 24 and the path that connects series arm resonator S1 and series arm resonator S2. Parallel arm resonator P3 is connected to between the ground formed by ground terminal 25 and the path that connects series arm resonator S2 and series arm resonator S3. Thus, parallel arm resonator P1 is connected at a position closer to input terminal Fin than parallel arm resonator P2, and parallel arm resonator P2 is connected at a position closer to input terminal Fin than parallel arm resonator P3.

The connection relationship between series arm resonators S1 to S3 and parallel arm resonators P1 to P3 may not necessarily be limited to what is illustrated in FIG. 4. The respective resonators may be connected as follows; parallel arm resonator P1 is connected to between the ground formed by ground terminal 21 and the path that connects series arm resonator S1 and series arm resonator S2, parallel arm resonator P2 is connected to between the ground formed by ground terminal 24 and the path that connects series arm resonator S2 and series arm resonator S3, and parallel arm resonator P3 is connected to between the ground formed by ground terminal 25 and the path that connects series arm resonator S3 and output terminal Fout. In this instance, input terminal Fin may be connected to series arm resonator S1.

A plurality of impedance adjustment circuits including switching element 3 and impedance element 4 are connected to ladder filter F. The impedance adjustment circuits include an impedance adjustment circuit I1, an impedance adjustment circuit I2, and an impedance adjustment circuit I3.

The impedance adjustment circuits (I1 to I3) are connected in series to the parallel arm resonators (P1 to P3) and each have a pair of impedance element 4 and switching element 3 connected in parallel to each other. This disclosure describes capacitor C (C1 to C3) and switch SW (SW1 to SW3), which are respectively examples of impedance element 4 and of switching element 3. Specifically, impedance adjustment circuit I1 includes a pair of capacitor C1 and switch SW1 connected in parallel to each other. This impedance adjustment circuit is connected in series to parallel arm resonator P1. Impedance adjustment circuit I2 includes a pair of capacitor C2 and switch SW2 connected in parallel to each other. This impedance adjustment circuit is connected in series to parallel arm resonator P2. Impedance adjustment circuit I3 includes a pair of capacitor C3 and switch SW3 connected in parallel to each other. This impedance adjustment circuit is connected in series to parallel arm resonator P3.

In the first embodiment, the impedance adjustment circuits each having capacitor C and switch SW of parallel connection are connected in series to the parallel arm resonators between the ground and the path that connects input terminal Fin and output terminal Fout. Specifically, the impedance adjustment circuits are connected in series to between the ground and the parallel arm resonators. Capacitor C and switch SW may be connected to between the parallel arm resonator and the path that connects input terminal Fin and output terminal Fout. Being “connected” described herein includes both of direct connection and indirect connection. In this description, being “connected” includes indirect connection unless stated otherwise.

In this embodiment, capacitor C is impedance element 4 connected in series to the parallel arm resonator. The frequency fluctuation width of the filtering passband may depend on the constant of capacitor C. For instance, the filtering passband may have a broader frequency fluctuation width with a smaller constant of capacitor C. The constant of capacitor C, therefore, may be suitably decided depending on the frequency specs required of a filter to be used. Optionally, a variable capacitor, examples of which include varicap diode or DTC (Digital Tunable Capacitor), may instead be used. This may allow fine adjustment of the frequency fluctuation width.

Switch SW is a SPST (Single Pole Single Throw) switching element in which one of terminals is connected to between capacitor C and the parallel arm resonator and the other is connected to the ground. Electrically conductive state (ON) or non-conductive state (OFF) is selected in response to a control signal transmitted from a controller (not illustrated in the drawings). Then, switch SW is controllably flipped to ON or OFF such as with control circuitry, so that the path from the ground to between the parallel arm resonator and capacitor C is rendered electrically conducted or non-conducted.

An inductor L1 is connected to between the ground formed by ground terminal 26 and the path to and from series arm resonator S3 and output terminal Fout. The inductor described herein is just an example and may be replaceable with a capacitor or a resistor.

Radio-frequency module 100 thus configured includes a tunable filter having a passband variable in response to changeover by switch SW to and from the electrically conductive state and non-conductive state.

Ground terminal 21 is an example of the “first ground terminal” as claimed herein. Likewise, ground terminals 22, 23 and 24 are respectively examples of the “second ground terminal”, “third ground terminal” and “fourth ground terminal” as claimed herein. Parallel arm resonator P1 is an example of the “first parallel arm resonator” as claimed herein. Parallel arm resonator P2 is an example of the “second parallel arm resonator” as claimed herein.

Impedance adjustment circuits I1 and I2 are respectively examples of the “first impedance adjustment circuit” and “second Impedance adjustment circuit” as claimed herein.

### Layout of Vias

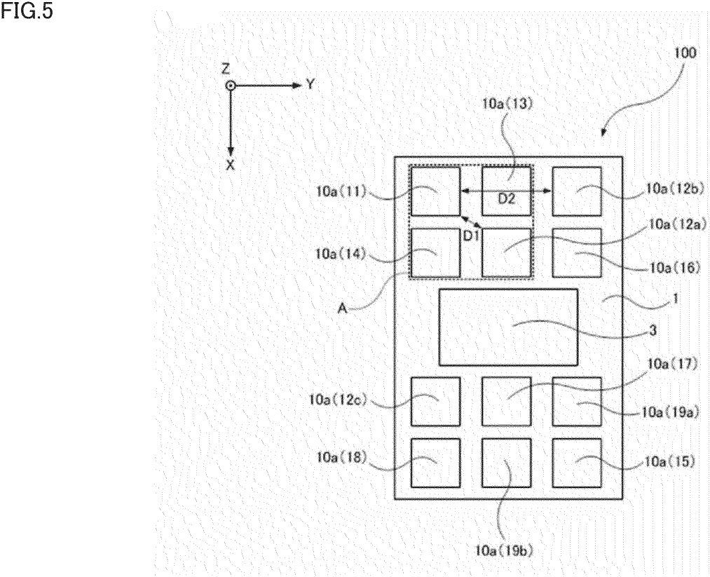

In radio-frequency module 100, a plurality of vias 10 is disposed in a predetermined layout to avoid possible property degradation resulting from unwanted coupling of vias 10. The predetermined layout is hereinafter described. FIG. 5 is a layout diagram of vias 10 in radio-frequency module 100. This drawing is a cross-sectional view of FIG. 2 along A-A′ line.

The description given below focuses on the layout of, among all of vias 10 of structure 1, vias 10a that connect wiring layer 5 and terminal electrodes 8.

Vias 10a include vias 11, 12a to 12c, 13, 14 and 15. In the description below, vias 12a to 12c may be collectively referred to as via(s) 12. Via 11 connects input terminal 20a and filtering element 2. Via 12a connects ground terminal 21 and the impedance adjustment circuit having switching element 3 and impedance element 4. Via 13 connects ground terminal 22 and a ground pattern included in wiring layer 5. Via 14 connects ground terminal 23 and the ground pattern included in wiring layer 5 Via 15 connects output terminal 20b and wiring layer 5. Vias 10a connected to ground terminals 21 to 28 may be referred to as ground vias.

Via 11, instead of directly connecting input terminal 20a and filtering element 2, may be disposed on the path that connects input terminal 20a and filtering element 2. Likewise, vias 10a including via 11 may not necessarily be limited to direct connection between two elements or two positions. These vias may be each disposed on a path between two elements or two positions.

In FIG. 4, via 11 represents a portion that connects input terminal 20a and input terminal Fin. Via 12a represents a portion that connects the ground and impedance adjustment circuit I1, via 12b represents a portion that connects the ground and impedance adjustment circuit I2, and via 12c represents a portion that connects the ground and impedance adjustment circuit I3. Though not illustrated in FIG. 4, via 13 is a portion that connects the ground and the path that connects input terminal 20a and input terminal Fin. Via 14 is a portion that connects the ground and the path that connects output terminal 20b and input terminal Fin. Via 15 represents a portion that connects output terminal Fout and output terminal 20b.

Vias 12 include via 12a that connects ground terminal 21 and impedance adjustment circuit I1, via 12b that connects ground terminal 24 and impedance adjustment circuit I2, and via 12c that connects ground terminal 25 and impedance adjustment circuit I3.

Vias 10a further include vias 16, 17, 18 and 19. Via 16 connects filtering element 2 and inductor L1; an example of the impedance element. Via 17 is a via for power source, which provides connection between the power source terminal of switching element 3 and an external terminal for power source (one of terminal electrodes 8). Via 18 is a via for control, which provides connection between the control terminal of switching element 3 and an external terminal for control (one of terminal electrodes 8). Vias 19 include vias 19a and 19b. Via 19a connects ground terminal 27 and the ground pattern included in wiring layer 5. Via 19b connects ground terminal 28 and the ground pattern included in wiring layer 5.

As illustrated in FIG. 5, a plurality of vias 10b in radio-frequency module 100 are arranged in the matrix of 3×4 rows. Supposing that via 11 is at the leftmost position in the first row from the top in FIG. 5, via 10a (11), via 10a (13) and via 10a (12b), from the left facing the drawing, are disposed in the first row. Likewise, via 10a (14), via 10a (12a) and via 10a (16), from the left facing the drawing, are disposed in the second row, via 10a (12c), via 10a (17) and via 10a (19a), from the left facing the drawing, are disposed in the third row, and via 10a (18), via 10a (19b) and via 10a (15), from the left facing the drawing, are disposed in the fourth row.

Supposing that “A” refers to a smallest rectangular region that encompasses vias 11 and 12a, via 13 is located in this rectangular region A. Vias 11 and 12a are inscribed in rectangular region A. Rectangular region A, if more particularly defined, is a smallest region among any rectangular regions that can encompass the outer edges of all of vias 11 and 12a. Vias 11 and 12a are located at diagonally opposite corners of this rectangular region. The outer edge of via 13 is located in rectangular region A.

Rectangular region A may be a smallest region that encompasses vias 11 and 12b or may be a smallest region that encompasses vias 11 and 12c. In case there are a plurality of vias 12 that connect ground terminal 21 and the impedance adjustment circuit having switching element 3 and impedance element 4, rectangular region A may be defined by any ones of vias 12 and 11, however, should include at least part of via 13.

Vias 11 and 13 are next to each other in rectangular region A. In other words, there is no other via between vias 11 and 13.

Via 14 is also located in rectangular region A. To be more accurate, the outer edge of via 14 is within rectangular region A.

There is a smaller distance between vias 11 and 12a than between vias 11 and 12b. In detail, the distance between via 11 and via 12a that connects ground terminal 21 and impedance adjustment circuit I1 is defined as a distance D1. The distance between via 11 and via 12b that connects ground terminal 24 and impedance adjustment circuit I2 is defined as a distance D2. To be more accurate, distance D1 is a distance that allows the outer edges of vias 11 and 12a to connect to each other in a shortest route, and D2 is a distance that allows the outer edges of vias 11 and 12b to connect to each other in a shortest route. In this instance, distance D1 is shorter than distance D2, as illustrated in FIG. 5.

Vias 15 and 11 are disposed with switching element 3 being disposed therebetween. Further, the rightmost via 15 in the bottom row and the leftmost via 11 in the first row from the top are disposed at diagonally opposite corners. In other words, vias 11 and 15 are spaced apart from each other by a greater distance than any other inter-via distances except the distance between vias 12a and 18.

Via 11 is an example of the “first via” as claimed herein. Likewise, via 12 is an example of the “second via” as claimed herein, via 13 is an example of the “third via” as claimed herein, via 14 is an example of the “fourth via” as claimed herein, and via 15 is an example of the “fifth via” as claimed herein. Distance D1 represents the “first distance” as claimed herein, while distance D2 represents the “second distance” as claimed herein.

### Effects

In radio-frequency module 100 according to the first embodiment, via 13 is located in the smallest rectangular region A encompassing vias 11 and 12. Thus, the distance between vias 11 and 13 is shorter than the distance between vias 11 and 12. Thus, via 13 may serve to reliably control signal skipping that possibly occurs between vias 11 and 12. The shorter distance between vias 11 and 13 than between vias 11 and 12 may serve to control the occurrence of signal skipping between vias 11 and 12, thereby reducing the risk of property degradation.

This effect is described in detail below referring to FIG. 4. Via 11 connects input terminal 20a and filtering element 2, and via 12a connects impedance adjustment circuit I1 and the ground formed by ground terminal 21. For instance, a signal E1, which is an input signal, flows out from input terminal 20a toward input terminal Fin of the filter. Then, signal E1 is converted into a signal E2 through parallel arm resonator P1 and capacitor C1 or switch SW1. Of these two signals E1 and signal E2, signal E1 is a signal before passing through any elements including the filter, while signal E2 is a signal that already passed through the elements including the filter. Amid such signal behaviors, signals which are neither the signals before conversion nor the signals after conversion are flowing through via 13. Via 13 (or ground via) that receives the flow of power source and control signals that differ from the input signal is disposed at a position away by a shorter distance from via 11 that receives the unconverted signal flow than the distance between this via 11 and via 12 that receives the converted signal flow. This may successfully prevent signal skipping and any interference between signals before and after conversion. In consequence of that, radio-frequency module 100 may be unlikely to degrade in property.

This disclosure so far described the controllability of signal skipping that may result from unwanted coupling of via 11 connected to input terminal 20a and via 12 that connects the ground and the impedance adjustment circuit. A case example is discussed below, in which via 11 connected to input terminal 20a and via 12 connected to the impedance adjustment circuit are undesirably coupled to each other.

Supposing that the impedance adjustment circuit is a tunable filter, as in the first embodiment, having a passband variable in response to changeover by switch SW to and from the electrically conductive state and non-conductive state, the filtering passband may be difficult to change to any desired passband if vias 11 and 12 are coupled to each other. As a result, desired filtering properties may be difficult achieve.

Unwanted coupling of vias may invite such an unfavorable event as signal skipping, leading to degradation of filtering properties. To avoid this problem, this disclosure seeks to offer a well-devised layout of vias that are connected to the impedance adjustment circuits.

In radio-frequency module 100 according to the first embodiment, via 13 is connected to ground terminal 22. This may be advantageous in that inter-via signal skipping may be more reliably controllable. Putting this advantage otherwise, via 13 exerts a good shielding effect against vias 11 and 12.

To be specific, ground via 13 is disposed at a position away by a shorter distance from via 11 that receives the unconverted signal flow than the distance between this via 11 and via 12 that receives the converted signal flow. In case a signal skips from via 11 to via 13, the signal is short-circuited to the ground, making the signal difficult to further skip from via 13 to any other via. A good shielding effect may be achievable by thus disposing ground via 13 at a position away by a shorter distance from via 11 that receives the unconverted signal flow than the distance between via 11 and via 12 that receives the converted signal flow. The ground via refers to, among all of vias 10, a via(s) connected to the ground in at least part thereof.

In radio-frequency module 100 according to the first embodiment, via 14 connected to ground terminal 23 is also located in rectangular region A. This may achieve a better shielding effect against vias 11 and 12.

To be specific, via 14 having grounding properties is also located in rectangular region A. Vias 11 and 13, as well as vias 11 and 14, are spaced apart from each other by a shorter distance than between vias 11 and 12. This may achieve a better shielding effect against vias 11 and 12.

In radio-frequency module 100 according to the first embodiment, switching element 3, filtering element 2 and impedance element 4 at least partly overlap one another in a plan view in Z direction. This may result in a higher layout density, increasing the likelihood of property degradation resulting from, for example, signal skipping. This embodiment, therefore, may demonstrate a notable effect in the controllability of property degradation.

In radio-frequency module 100 according to the first embodiment, impedance element 4 is interposed between switching element 3 and filtering element 2 in Z direction. This may also result in a higher layout density, demonstrating a notable effect in the controllability of property degradation.

In radio-frequency module 100 according to the first embodiment, the impedance element and the switching element are connected in parallel to each other in the impedance adjustment circuit. This parallel connection provides two paths; a path formed by the via that connects the impedance element and the ground, and a path formed by the via that connects the switching element 3 and the ground, allowing effective control of any impact from via 11 being coupled to another via.

In radio-frequency module 100 according to the first embodiment, distance D1 between via 11 and via 12a that connects impedance adjustment circuit I1 and ground terminal 21 is shorter than distance D2 between via 11 and via 12b that connects impedance adjustment circuit I2 and ground terminal 24. Signal skipping between vias 11 and 12b may be more undesirable than signal skipping between vias 11 and 12a. By setting distance D2 to a greater dimension than distance D1, such undesired signal skipping between vias 11 and 12b may be unlikely to occur.

Thus far were described the reasons why signal skipping between vias 11 and 12b is more undesirable than signal skipping between vias 11 and 12a. Once again, the reasons are hereinafter described in more detail with reference to FIG. 4. A signal E3 flows through impedance adjustment circuit I2 and the ground. In comparison between signals E3 and E2, signal E3 is a signal that already passed through capacitor C2, parallel arm resonator P2, and also series arm resonator S1. This indicates a greater signal difference between signals E1 and E3 than between signals E1 and E2. Based on that, signal skipping between vias 11 and 12b is considered more undesirable than signal skipping between vias 11 and 12a, and distance D1 between vias 11 and 12 is preferably shorter than distance D2 between vias 11 and 12b.

A case example was thus far described in which signal skipping was controlled between via 11 connected to input terminal 20a and via 12 that connects the impedance adjustment circuit and the ground. Signal skipping, if it occurs in the path between input terminal 20a and output terminal 20b, may certainly degrade filtering properties as well.

In radio-frequency module 100 according to the first embodiment, via 11 and via 15 connected to output terminal Fout of filtering element 2 are disposed with switching element 3 being interposed therebetween in the plan view in Z direction. Thus, possible signal skipping between vias 11 and 15 may be reliably avoidable.

In radio-frequency module 100 according to the first embodiment, vias 11 and 15 are disposed at diagonally opposite corners of structure 1 in the plan view in Z direction. In this instance, the distance between vias 11 and 15 is greater than distances between any other vias, which may promise more effective control of signal skipping between vias 11 and 15.

In radio-frequency module 100 according to the first embodiment, vias 11 and 13 are next to each other. This may be rephrased that there is no other via between vias 11 and 13. Thus, signal skipping from via 11 to any via but via 13 may be prevented by via 13 closest to via 11.

The controllability of signal skipping between vias 11 and 12a was so far described, with a focus being placed on via 11 connected to input terminal 20a. This signal skipping control is applicable likewise to via 15 connected to output terminal 20b. Signal skipping between vias 15 and 12c may be successfully prevented by disposing vias 19 and 15 next to each other.

Signal skipping between vias 15 and 12c is described in detail referring to FIGS. 4 and 5. In FIG. 4, via 15 represents a portion that connects input terminal Fin and output terminal 20b. Via 12c represents a portion that connects the ground and the impedance adjustment circuit I3. Though not illustrated in FIG. 4, via 19 represents a portion that connects the ground and the path between output terminal 20b and output terminal Fout.

For control of signal skipping between vias 15 and 12c, via 19 may preferably be disposed in a smallest rectangular region that encompasses vias 15 and 12c, as illustrated in FIG. 5. Thus, via 19 may serve to reliably control signal skipping that possibly occurs between vias 15 and 12c. The shorter distance between vias 15 and 19 than between vias 15 and 12c may serve to control the occurrence of signal skipping, thereby reducing the risk of property degradation.

### Modified Example of First Embodiment

Modified examples of radio-frequency module 100 according to the first embodiment are hereinafter described.

### (6.1) First Modified Example

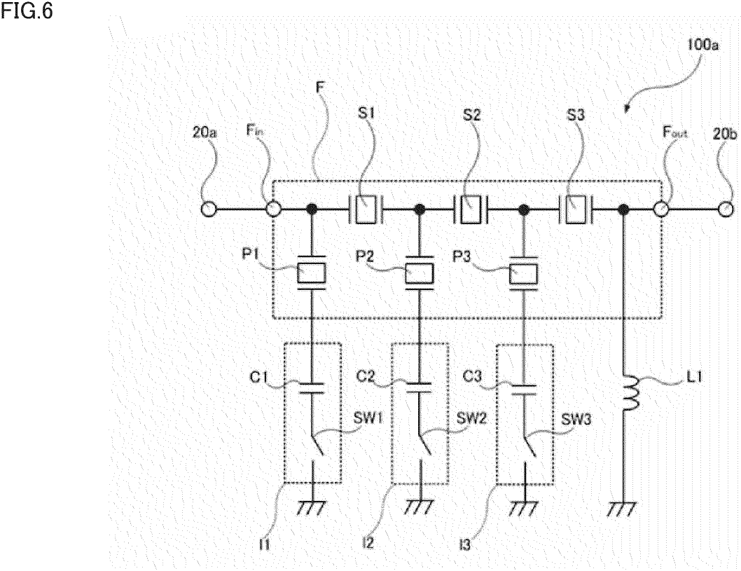

FIG. 6 is an equivalent circuit diagram of a radio-frequency module 200 according to a first modified example. In radio-frequency module 100 according to the first embodiment, capacitor C1 and switch SW1 are connected in parallel to each other in impedance adjustment circuit I1, as illustrated in FIG. 4. Instead, capacitor C1 and switch SW1 may be connected in series to each other, as illustrated in FIG. 6. In the impedance adjustment circuit including switching element 3 and impedance element 4, switching element 3 and impedance element 4 may be thus connected in series to each other.

Radio-frequency module 100a according to the first modified example is configured similarly to radio-frequency module 100 according to the first embodiment except the connection relationship between switching element 3 and impedance element 4. The layout of vias is hence similar to the layout employed in radio-frequency module 100 according to the first embodiment. Specifically, via 13 is disposed in the smallest rectangular region A that encompasses vias 11 and 12. Thus, via 13 may serve to reliably control signal skipping between vias 11 and 12. This may conduce to effective control of the occurrence of signal skipping, thereby reducing the risk of property degradation.

By having capacitor C1 (impedance element 4) and switch SW1 (switching element 3) connected in series to each other, there is only one path (via 12a) that connects impedance adjustment circuit I1 and ground terminal 21. This may advantageously provide a higher degree of freedom in the layout of vias, conducing to effective control of signal skipping.

### (6.2) Second Modified Example

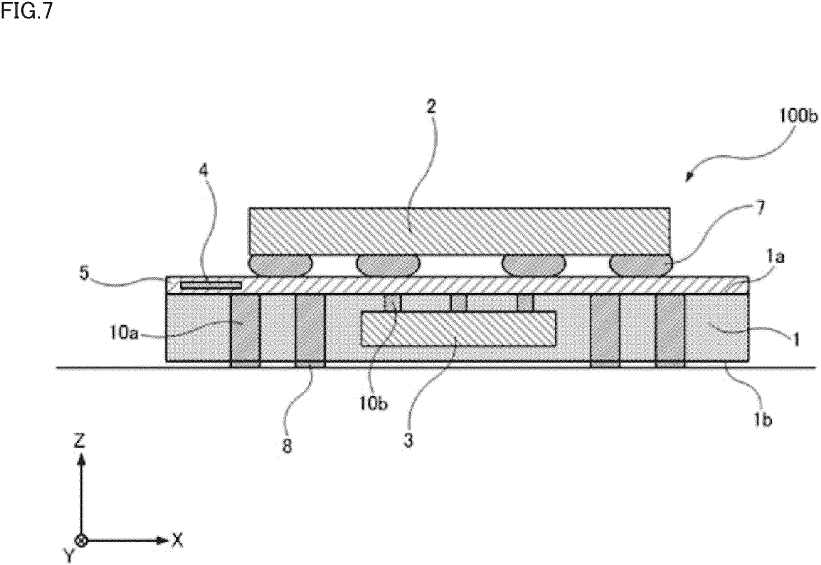

FIG. 7 is a cross-sectional view of a radio-frequency module 100b according to a second modified example. In radio-frequency module 100 according to the first embodiment, filtering element 2, impedance element 4 and switching element 3 overlap one another in the plan view in Z direction, as illustrated in FIG. 2. Optionally, such an overlap among filtering element 2, impedance element 4 and switching element 3 may not necessarily be required, as illustrated in FIG. 7.

Radio-frequency module 100b according to the second modified example is configured similarly to radio-frequency module 100 according to the first embodiment except the positional relationship among filtering element 2, switching element 3 and impedance element 4 in structure 1. This radio-frequency module is configured similarly to radio-frequency module 100 according to the first embodiment in terms of the layout of vias and is thus allowed to effectively control signal skipping and resulting property degradation.

Because of no restriction on the location of impedance element 4 in wiring layer 5, the degree of freedom in designing may be favorably improved.

The positional relationship among filtering element 2, switching element 3 and impedance element 4 may be defined otherwise. Filtering element 2, switching element 3 and impedance element 4 may not necessarily overlap entirely with one another in the plan view. For example, these elements may be disposed in a manner that they only partly overlap one another in the plan view.

### (6.3) Third Modified Example

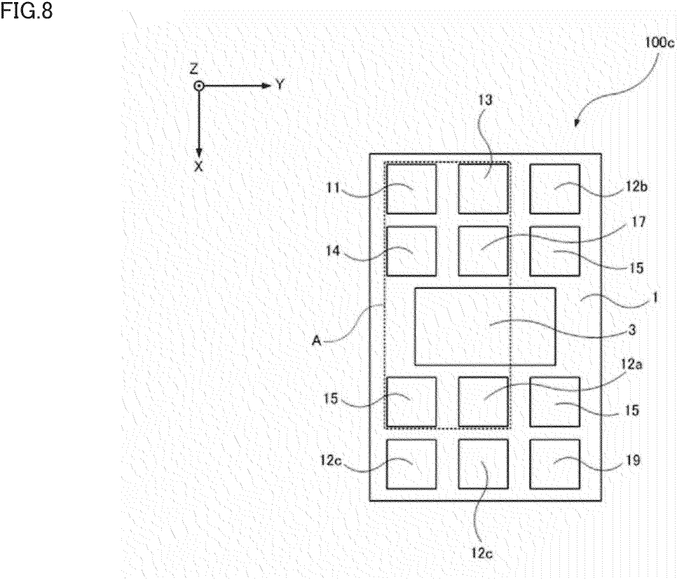

FIG. 8 is a layout diagram of vias in a radio-frequency module 100c according to a third modified example. In radio-frequency module 100 according to the first embodiment, switching element 3 is not interposed between vias 11 and 12a, as illustrated in FIG. 5. Optionally, vias 11 and 12a may be disposed with switching element 3 being interposed therebetween, as illustrated in FIG. 8.

A plurality of vias 10b in radio-frequency module 100c are arranged in the matrix of 4×3 rows. Supposing that via 11 is at the leftmost position in the first row from the top in FIG. 8, via 11, via 13 and via 12b (12), from the left facing the drawing, are disposed in the first row. Likewise, via 14, via 17 and via 15, from the left facing the drawing, are disposed in the second row, via 15, via 12a (12) and via 15, from the left facing the drawing, are disposed in the third row, and via 12c (12), via 12c (12) and via 19, from the left facing the drawing, are disposed in the fourth row.

In radio-frequency module 100c, via 13 is located in a rectangular region A when this is defined as a smallest rectangular region encompassing vias 11 and 12a, similarly to radio-frequency module 100 according to the first embodiment. This may conduce to effective control of the occurrence of signal skipping, thereby reducing the risk of property degradation. Vias 11 and 12a are disposed with switching element 3 being disposed therebetween. To be specific, via 11, switching element 3 and via 12a are arranged in this order in X direction in FIG. 8. In comparison with radio-frequency module 100 according to the first embodiment, vias 11 and 12a are further spaced apart from each other, and switching element 3 is interposed between vias 11 and 12a. This may advantageously ensure an adequate distance between the vias, allowing them to be isolated from each other. As a result, signal skipping between vias 11 and 12a may be more effectively controlled.

### Second Embodiment

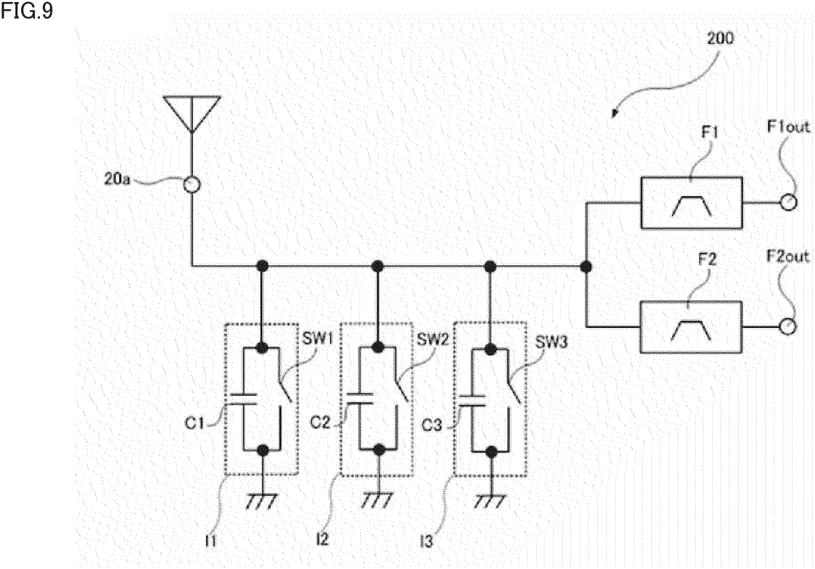

FIG. 9 is an equivalent circuit diagram of a radio-frequency module 200 according to a second embodiment. In radio-frequency module 100 according to the first embodiment, the impedance adjustment circuits are connected in series to the parallel arm resonators between the ground and the path that connects input terminal Fin and output terminal Fout, as illustrated in FIG. 4. Optionally, the impedance adjustment circuits may be connected to between input-output terminal 20 (20a) and the path to and from filtering elements F1 and F2, as illustrated in FIG. 9. In this instance, the impedance adjustment circuits may be matching circuits.

Radio-frequency module 200 is configured similarly to radio-frequency module 100 according to the first embodiment except the positions of connection of the impedance adjustment circuits. This radio-frequency module is configured similarly to radio-frequency module 100 according to the first embodiment in terms of the layout of vias and is thus allowed to effectively control signal skipping and resulting property degradation.

### Modified Example of Second Embodiment

A modified example of radio-frequency module 200 according to the second embodiment is hereinafter described.

### (8.1) Fourth Modified Example

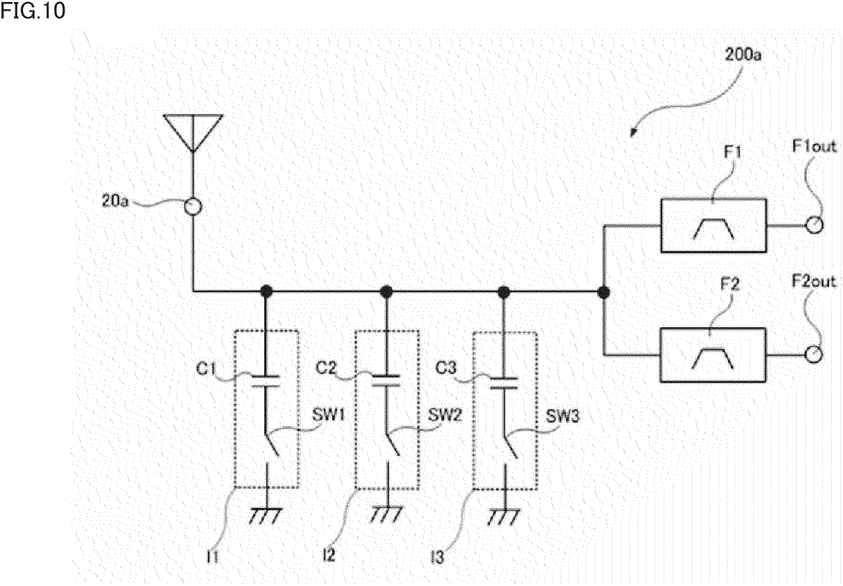

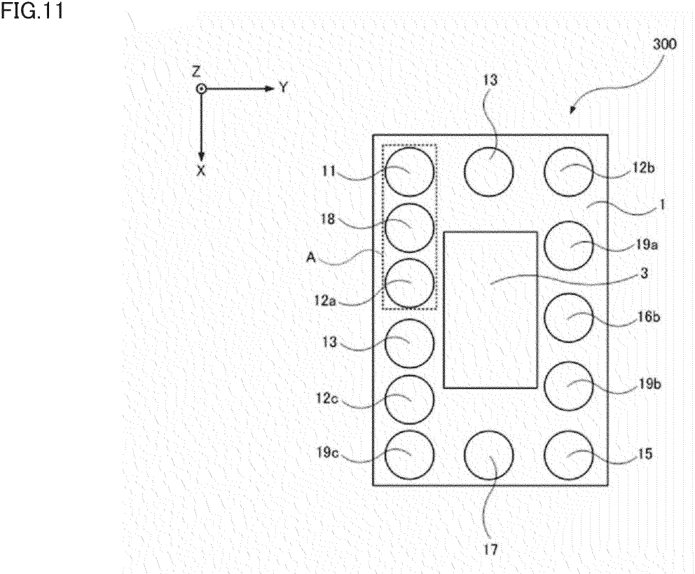

FIG. 10 is an equivalent circuit diagram of a radio-frequency module 200a according to a fourth modified example. In radio-frequency module 200 according to the second embodiment, capacitor C1 and switch SW1 are connected in parallel to each other in impedance adjustment circuit I1, as illustrated in FIG. 10. Instead, capacitor C1 and switch SW1 may connected in series to each other, as illustrated in FIG. 11. In the impedance adjustment circuit including switching element 3 and impedance element 4, switching element 3 and impedance element 4 may be thus connected in series to each other.

Radio-frequency module 200a according to the fourth modified example is configured similarly to radio-frequency module 200 according to the second embodiment except the connection relationship between switching element 3 and impedance element 4. This radio-frequency module is configured similarly to the second embodiment in terms of the layout of vias and is thus allowed to effectively control signal skipping and resulting property degradation.

By having capacitor C1 (impedance element 4) and switch SW1 (switching element 3) connected in series to each other, there is only one path (via 12a) that connects impedance adjustment circuit I1 and ground terminal 21. This may advantageously provide a higher degree of freedom in the layout of vias, conducing to effective control of signal skipping.

A case example is discussed below, in which via 11 connected to input terminal 20a and via 12 connected to the impedance adjustment circuit are undesirably coupled to each other. In case the impedance adjustment circuit is a matching circuit as described in the second embodiment, a desired level of matching may be difficult to achieve if vias 11 and 12 are coupled to each other. As a result of the matching failure, desired filtering properties may be difficult to obtain, and the radio-frequency module may accordingly fail to obtain desired properties.

Unwanted coupling of vias may invite such an unfavorable event as signal skipping, leading to degradation of filtering properties. To avoid this problem, this disclosure seeks to offer a well-devised layout of vias that are connected to the impedance adjustment circuits.

### Third Embodiment

FIG. 11 is a layout diagram of vias in a radio-frequency module 300 according to a third embodiment. Radio-frequency module 300 according to the third embodiment is configured similarly to radio-frequency module 100 according to the first embodiment except the layout of vias.

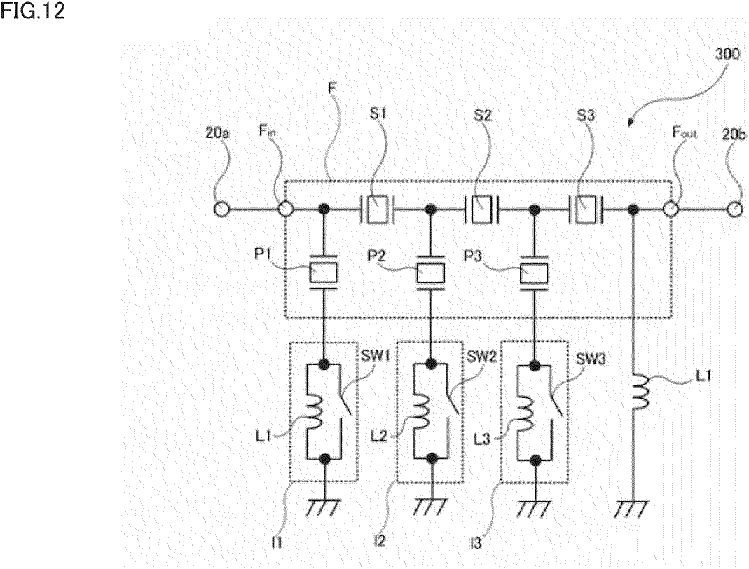

As illustrated in FIG. 11, a plurality of vias 10b in radio-frequency module 300 are arranged in a manner that surround switching element 3. Supposing that vertical rows are first to third rows from the left facing the drawing of FIG. 11 (direction opposite to the arrow of Y axis), via 11 is on the first vertical row, via 13 is on the second vertical row, and via 12b (12) is on the first vertical row. On the first vertical row in FIG. 12, from the top (direction opposite to the arrow of X axis) downward, via 11, via 18, via 12a, via 13, via 12c and via 19c are arranged in this order. On the second vertical row are arranged, from the top downward, via 13 and via 17 in this order. On the third vertical row are arranged, from the top downward, via 12b, via 19a, via 16b, via 19b, and via 15 in this order.

Supposing that a smallest region encompassing vias 11 and 12a (12) is a rectangular region A, via 18 is located in rectangular region A. This may allow via 18 to prevent signal skipping that possibly occurs between vias 11 and 12. The shorter distance between vias 11 and 18 than between vias 11 and 12 may serve to control the occurrence of signal skipping, thereby reducing the risk of property degradation.

Via 18 is a via for electrical conduction of a control signal that connects the control terminal of switching element 3 and an external terminal for control. Via 18 for electrical conduction of a signal that differs from the input and output signals for vias 11 and 12 is thus interposed between these vias. Signal skipping between vias 11 and 12 may be thereby reliably preventable. In this instance, a via for power source may be used instead of the via for electrical conduction of a control signal.

Vias 10 may each have a cylindrical shape extending in Z direction. Putting this shape otherwise, the vias may each have a circular shape in cross section in a cross-sectional view of structure 1 in Z direction, as illustrated in FIG. 11. Comparing vias 10 thus shaped with rectangular vias, fewer portions of such vias 10 are faced against each other, conducing to effective control of inter-via signal skipping.

FIG. 12 is an equivalent circuit diagram of radio-frequency module 300. In radio-frequency module 100 according to the first embodiment, impedance element 4 in the impedance adjustment circuit is a capacitor in the circuit configuration, as illustrated in FIG. 4. Instead, impedance element 4 in the impedance adjustment circuit may be an inductor, as illustrated in FIG. 12.

Impedance adjustment circuit I1 includes a pair of inductor L1 and switch SW1 connected in parallel to each other. This impedance adjustment circuit is connected in series to parallel arm resonator P1. Impedance adjustment circuit I2 includes a pair of inductor L2 and switch SW2 connected in parallel to each other. This impedance adjustment circuit is connected in series to parallel arm resonator P2. Impedance adjustment circuit I3 includes a pair of inductor L3 and switch SW3 connected in parallel to each other. This impedance adjustment circuit is connected in series to parallel arm resonator P3.

In the third embodiment, the impedance adjustment circuits each having inductor L and switch SW of parallel connection are connected in series to the parallel arm resonators between the ground and the path that connects input terminal Fin and output terminal Fout. Specifically, the impedance adjustment circuits are connected in series to between the ground and the parallel arm resonators. Inductor L and switch SW may be connected to between the parallel arm resonator and the path that connects input terminal Fin and output terminal Fout.

### Fourth Embodiment

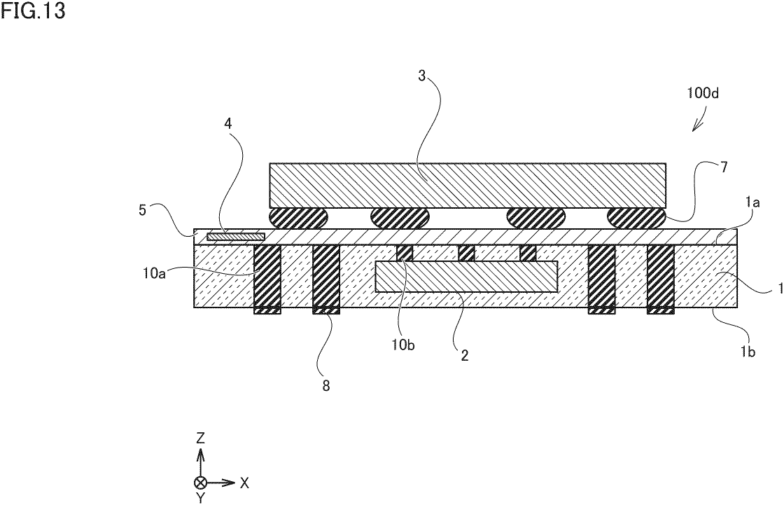

FIG. 13 is a cross-sectional view of a radio-frequency module 100d according a fourth embodiment. Radio-frequency module 100d according to the fourth embodiment is configured similarly to radio-frequency module 100b according to the second modified example except positions at which filtering element 2 and switching element 3 are arranged.

The positions of filtering element 2 and of switching element 3 are exchanged each other in radio-frequency module 100d illustrated in FIG. 13. Filtering element 2 is embedded in structure 1, while switching element 3 is disposed on first main surface 1a with solder bumps 7 being interposed therebetween.

Radio-frequency module 100d according to the fourth embodiment is configured similarly to radio-frequency module 100 according to the first embodiment in terms of the layout of vias and is thus allowed to effectively control signal skipping and resulting property degradation.

Because of no restriction on the locations of filtering element 2 and switching element 3, the degree of freedom in designing may be favorably improved. It should be understood that filtering element 2 and switching element 3 may be both embedded in structure 1, or filtering element 2 and switching element 3 may be both disposed on first main surface 1a.

### Fifth Embodiment

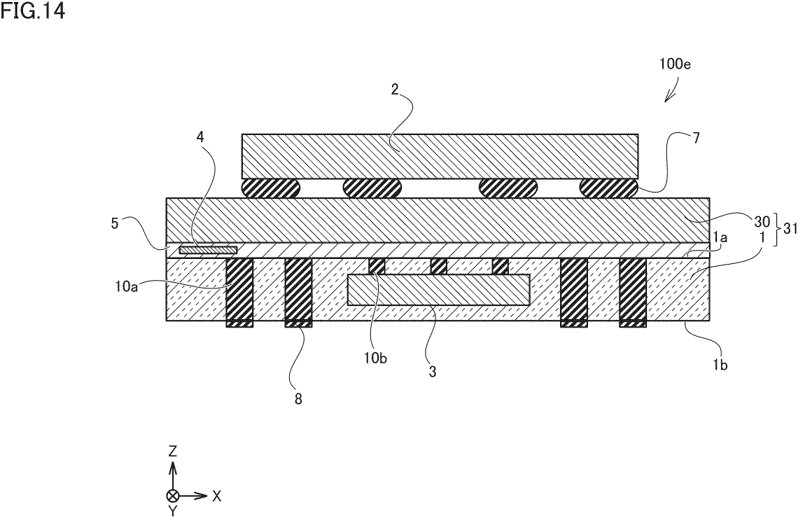

FIG. 14 is a cross-sectional view of a radio-frequency module 100e according to a fifth embodiment. Radio-frequency module 100e according to the fifth embodiment is configured similarly to radio-frequency module 100b according to the second modified example except that an Si substrate 30 is used.

In radio-frequency module 100e illustrated in FIG. 14, Si substrate 30 is disposed on a side of wiring layer 5 in the arrow direction of Z axis. In the description below, Si substrate 30 and structure 1 are collectively referred as a structure 31. Switching element 3 is embedded in structure 31.

Radio-frequency module 100e according to the fifth embodiment is configured similarly to radio-frequency module 100 according to the first embodiment in terms of the layout of vias and is thus allowed to effectively control signal skipping and resulting property degradation.

Radio-frequency module 100e according to the fifth embodiment including Si substrate 30 may offer the following advantages; protection of wiring layer 5 using the silicon substrate serving as a protective layer, and facilitated thickness adjustment by, for example, grinding the substrate.

### Modified Example of Fifth Embodiment

A modified example of radio-frequency module 100e according to the fifth embodiment is hereinafter described.

### (12.1) Fifth Modified Example

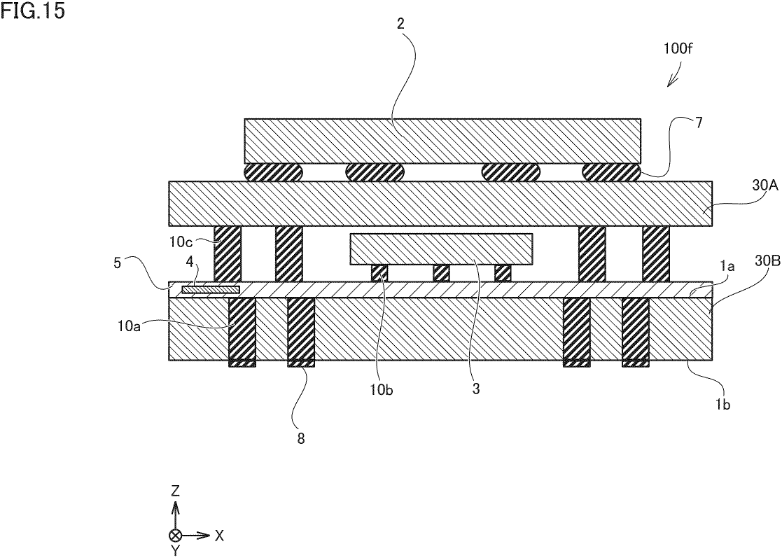

FIG. 15 is a cross-sectional view of a radio-frequency module 100f according to a fifth modified example. Radio-frequency module 100f according to the fifth modified example is configured similarly to radio-frequency module 100e according to the fifth embodiment except the following differences; vias 10c are disposed between an Si substrate 30A and wiring layer 5, switching element 3 and vias 10b are disposed on a side of wiring layer 5 in the arrow direction of Z axis, and structure 1 is replaced with an Si substrate 30B.

Vias 10c are disposed between Si substrate 30A and wiring layer 5. Si substrate 30A is electrically connected to wiring layer 5 through vias 10c. Vias 10c thus disposed form a space between Si substrate 30A and wiring layer 5. Switching element 3 is disposed in the space between Si substrate 30A and wiring layer 5.

Radio-frequency module 100f according to the fifth modified example is configured similarly to radio-frequency module 100 according to the first embodiment in terms of the layout of vias and is thus allowed to effectively control signal skipping and resulting property degradation.

Radio-frequency module 100f according to the fifth embodiment is further advantageous in that vias 10c are formed between Si substrate 30A and wiring layer 5, which allows switching element 3 to be disposed between wiring layer 5 and Si substrate 30A. In radio-frequency module 100f according to the fifth embodiment, switching element 3 and vias 10b are disposed on a side of wiring layer 5 in the arrow direction of Z axis. In this structure, switching element 3 may be mounted in this module after the formation of structure 1 and wiring layer 5 is over. In radio-frequency module 100f according to the fifth embodiment in which Si substrate 30A and Si substrate 30B constitute structure 1, the fabrication of radio-frequency module 100f may be completed in a semiconductor process.

### Sixth Embodiment

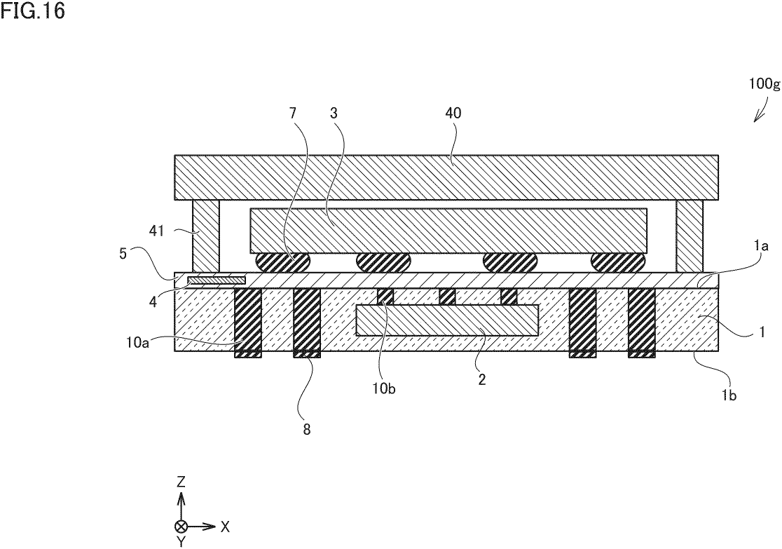

FIG. 16 is a cross-sectional view of a radio-frequency module 100g according to a sixth embodiment. Radio-frequency module 100g according to the sixth embodiment is configured similarly to radio-frequency module 100b according to the second modified example except that this module is further equipped with a cover 40 and supporters 41 that support cover 40.

Radio-frequency module 100g illustrated in FIG. 16 has cover 40 used to cover filtering element 2 and formed using, for example, an Si substrate. Supporters 41 are disposed between cover 40 and wiring layer 5 to support cover 40. Supporters 41 may each have a wall-like shape that extends in Y direction or may have a columnar shape that extends in Z direction.

Radio-frequency module 100g according to the sixth embodiment is configured similarly to radio-frequency module 100 according to the first embodiment in terms of the layout of vias and is thus allowed to effectively control signal skipping and resulting property degradation.

In radio-frequency module 100g according to the sixth embodiment, filtering element 2 is covered with cover 40. This may allow radio-frequency module 100g to improve in strength.

### Seventh Embodiment

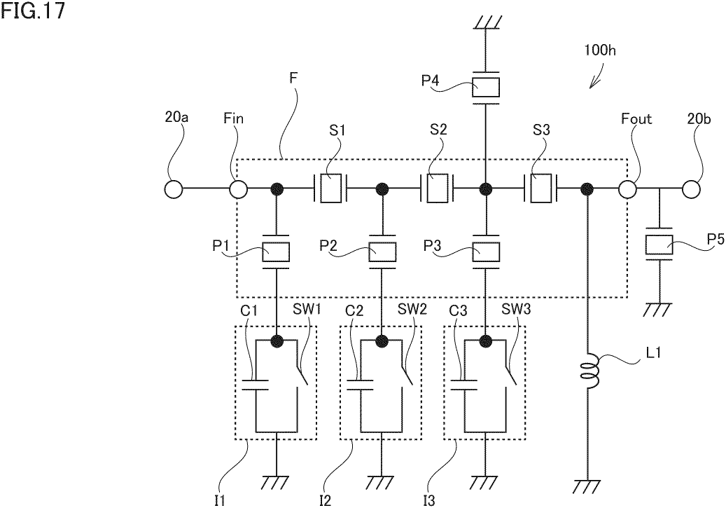

FIG. 17 is an equivalent circuit diagram of a radio-frequency module 100h according to a seventh embodiment. Radio-frequency module 100 according to the first embodiment is equipped with parallel arm resonators P1 to P3 that are connected to between the ground and the path that connects input terminal Fin and output terminal Fout. Radio-frequency module 100h illustrated in FIG. 17 is further equipped with parallel arm resonators P4 and P5. Parallel arm resonator P4 is connected to between the ground formed and the path that connects series arm resonator S2 and series arm resonator S3. Parallel arm resonator P5 is connected to between the ground and the path that connects output terminal 20b and output terminal Fout.

In the seventh embodiment, via 13 represents a portion that connects the ground and parallel arm resonator P4 or a portion that connects the ground and parallel arm resonator P5. Radio-frequency module 100h according to the seventh embodiment is configured similarly to radio-frequency module 100 according to the first embodiment except the position of via 13. The layout of vias is hence similar to the layout employed in radio-frequency module 100 according to the first embodiment. Specifically, via 13 is disposed in the smallest rectangular region A that encompasses vias 11 and 12. Thus, via 13 may serve to reliably control signal skipping between vias 11 and 12. This may conduce to effective control of the occurrence of signal skipping, thereby reducing the risk of property degradation.

In radio-frequency module 100h according to the seventh embodiment, via 13 represents a portion that connects the ground and parallel arm resonator P4 or a portion that connects the ground and parallel arm resonator P5. To be specific, ground via 13 is disposed at a position away by a shorter distance from via 11 that receives the unconverted signal flow than the distance between this via 11 and via 12 that receives the converted signal flow. In case a signal skips from via 11 to via 13, the signal is short-circuited to the ground. In radio-frequency module 100h according to the seventh embodiment, any signal, if skipped, may be directly short-circuited to the ground in a shortest route without capacitor C1; an exemplified impedance element. Thus, the signal may be unlikely to further skip from via 13 to any other via. This may offer a further enhanced shielding effect.

### Other Modified Examples

Thus far, the radio-frequency module disclosed herein was described in detail based on the embodiments and modified examples. This disclosure may not necessarily be limited to such embodiments and modified examples. This disclosure includes, in its scope, any other embodiments feasible by combining optional devices and elements of the embodiments and modified examples described so far, any other modified examples in which various modifications conceivable by those skilled in the art are applied to the embodiments and modified examples described herein without departing the scope of the technical idea and concept of this disclosure, and various devices and components embedded with the radio-frequency module disclosed herein.

In the first embodiment, for example, via 13 may not necessarily be connected to ground terminals 21 to 28 including ground terminal 22. Via 13 may be connected to a control terminal controlled by switching element 3.

In the first embodiment, via 14 may be located on the outside of rectangular region A.

In the first embodiment, impedance element 4 may not necessarily be interposed between switching element 3 and filtering element 2. In an example, impedance element 4 may be embedded in circuit board 70.

In the first embodiment, distance D1 between via 11 and via 12a that connects impedance adjustment circuit 11 and ground terminal 21 may be greater than or equal to distance D2 between via 11 and via 12b that connects impedance adjustment circuit I2 and ground terminal 24.

In the first embodiment, vias 11 and 15 may not necessarily be disposed at diagonally opposite corners of structure 1.

In the first embodiment, vias 11 and 13 may not necessarily be next to each other.

In the first embodiment, impedance element 4 may be a matching element, for example, an inductor, instead of the capacitor.

In the first embodiment, filtering element 2 may be a filter, for example, an LC filter, instead of the elastic wave device.

In the third embodiment, via 13 may not necessarily be interposed between 11 and 12.

### REFERENCE SIGNS LIST

1: structure, 1a: first main surface, 1b: second main surface, 2: filtering element, 3: switching element, 4: impedance element, 5: wiring layer, 7: solder bump, 8: terminal electrode, 9: protective layer, 10 to 19: via, 20, 20a, 20b: input-output terminal, 21 to 28: ground terminal, 30: Si substrate, 40: cover, 41: supporter, 70: circuit board, 80: electrode, 100: radio-frequency module, A: rectangular region, C: capacitor, D1: first distance, D2: second distance, E1 to E3: signal, F: ladder filter, F1: Filtering element, Fin: input terminal, L: inductor, P1 to P5: parallel arm resonator, S1 to S3: series arm resonator, SW, SW1 to SW3: switch

1. A radio-frequency module, comprising:
a structure comprising a first main surface and a second main surface that are opposed to each other;
a filtering element disposed on the first main surface of the structure;
a switching element embedded in the structure; and
an impedance element embedded in the structure and connected to the switching element and the filtering element, wherein
the switching element and the filtering element at least partially overlap each other in in a plan view in a normal direction to the first main surface,
an input-output terminal and a first ground terminal that are disposed on the second main surface of the structure,
the structure comprises a plurality of vias arranged in the normal direction to the first main surface,
the plurality of vias include a first via, a second via and a third via,
the first via connects the input-output terminal and the filtering element,
the second via connects the first ground terminal and an impedance adjustment circuit including the switching element and the impedance element,
the third via is located in a smallest rectangular region encompassing the first via and the second via in the plan view, and
the impedance element is interposed between the switching element and the filtering element in the normal direction to the first main surface.

2. The radio-frequency module according to claim 1, wherein a distance between the first via and the third via is shorter than a distance between the first via and the second via.

3. The radio-frequency module according to claim 1, wherein the third via is connected to a second ground terminal.

4. The radio-frequency module according to claim 1, wherein
the plurality of vias further include a fourth via connected to a third ground terminal, and
the fourth via is located in the rectangular region in the plan view.

5. The radio-frequency module according to claim 1, wherein the switching element, the filtering element and the impedance element at least partially overlap one another in the plan view.

6. The radio-frequency module according to claim 2, wherein the switching element, the filtering element and the impedance element at least partially overlap one another in the plan view.

7. The radio-frequency module according to claim 1, wherein the first via and the second via are disposed with the switching element being interposed therebetween.

8. The radio-frequency module according to claim 1, wherein
the filtering element is a ladder filter comprising a plurality of series arm resonators and a plurality of parallel arm resonators,
the plurality of parallel arm resonators include a first parallel arm resonator and a second parallel arm resonator,
the first parallel arm resonator is connected at a position closer to the input-output terminal than the second parallel arm resonator,
the radio-frequency module further comprises a plurality of the impedance adjustment circuits connected to the ladder filter,
the plurality of the impedance adjustment circuits include a first impedance adjustment circuit and a second impedance adjustment circuit,
the first impedance adjustment circuit is connected to the first parallel arm resonator, and the second impedance adjustment circuit is connected to the second parallel arm resonator, and
a first distance between the first via and the second via connecting the first impedance adjustment circuit and the first ground terminal is shorter than a second distance between the first via and the second via connecting the second impedance adjustment circuit and a fourth ground terminal.

9. The radio-frequency module according to claim 1, wherein
the input-output terminal is connected to an input terminal of the filtering element,
the plurality of vias further include a fifth via connected to an output terminal of the filtering element, and
the first via and the fifth via are disposed with the switching element being interposed therebetween in the plan view.

10. The radio-frequency module according to claim 9, wherein the first via and the fifth via are disposed at diagonally opposite corners of the structure in the plan view.

11. The radio-frequency module according to claim 1, wherein the impedance adjustment circuit is connected to between the input-output terminal and the filtering element.

12. The radio-frequency module according to claim 1, wherein the first via and the third via are next to each other.

13. The radio-frequency module according to claim 1, wherein the impedance element comprises a capacitor or an inductor.

14. The radio-frequency module according to claim 1, wherein the filtering element is an elastic wave device.

15. The radio-frequency module according to claim 1, wherein the third via is interposed between the first via and the second via.

16. The radio-frequency module according to claim 1, wherein the plurality of vias each have a shape of rectangular cuboid extending in the normal direction to the first main surface.

17. The radio-frequency module according to claim 1, wherein the plurality of vias each have a shape of cylinder extending in the normal direction to the first main surface.

18. The radio-frequency module according to claim 2, wherein the plurality of vias each have a shape of cylinder extending in the normal direction to the first main surface.

19. A radio-frequency module, comprising:
a structure comprising a first main surface and a second main surface that are opposed to each other;
a filtering element disposed on the first main surface of the structure;
a switching element embedded in the structure; and
an impedance element embedded in the structure and connected to the switching element and the filtering element, wherein
the switching element and the filtering element at least partially overlap each other in in a plan view in a normal direction to the first main surface,
an input-output terminal and a first ground terminal that are disposed on the second main surface of the structure,
the structure comprises a plurality of vias arranged in the normal direction to the first main surface,
the plurality of vias include a first via, a second via and a third via,
the first via connects the input-output terminal and the filtering element,
the second via connects the first ground terminal and an impedance adjustment circuit including the switching element and the impedance element,
the third via is located in a smallest rectangular region encompassing the first via and the second via in the plan view, and
the impedance element and the switching element are connected in parallel to each other in the impedance adjustment circuit.

20. A radio-frequency module, comprising:
a structure comprising a first main surface and a second main surface that are opposed to each other;
a filtering element disposed on the first main surface of the structure;
a switching element embedded in the structure; and
an impedance element embedded in the structure and connected to the switching element and the filtering element, wherein
the switching element and the filtering element at least partially overlap each other in in a plan view in a normal direction to the first main surface,
an input-output terminal and a first ground terminal that are disposed on the second main surface of the structure,
the structure comprises a plurality of vias arranged in the normal direction to the first main surface,
the plurality of vias include a first via, a second via and a third via,
the first via connects the input-output terminal and the filtering element,
the second via connects the first ground terminal and an impedance adjustment circuit including the switching element and the impedance element,
the third via is located in a smallest rectangular region encompassing the first via and the second via in the plan view, and
the impedance element and the switching element are connected in series to each other in the impedance adjustment circuit.
